(19) United States
(12) Patent Application Publication
(10) Pub. No.: US 2026/0214978 A1
(43) Pub. Date: Jul. 23, 2026

(54) SEMICONDUCTOR DEVICE AND FORMATION METHOD THEREOF

(71) Applicant: TAIWAN SEMICONDUCTOR MANUFACTURING COMPANY, LTD., Hsinchu (TW)

(72) Inventors: Hung-Kun LO, New Taipei City (TW); Ku-Feng YANG, Hsinchu County (TW); Szuya LIAO, Hsinchu County (TW); Pei-Ren JENG, Hsinchu County (TW); Ji-Yin TSAI, Hsinchu County (TW)

(73) Assignee: TAIWAN SEMICONDUCTOR MANUFACTURING COMPANY, LTD., Hsinchu (TW)

(21) Appl. No.: 19/033,206

(22) Filed: Jan. 21, 2025

(51) Int. Cl. H10D 84/85; H01L 21/02; H10D 30/00; H10D 30/01; H10D 62/10; H10D 62/13; H10D 84/01

(52) U.S. Cl. CPC H10D 84/851; H10D 30/0191; H10D 30/502; H10D 62/121; H10D 62/151; H10D 84/017; H10P 14/6922

(57) ABSTRACT

A method comprises the following steps. A first semiconductor nanostructure is formed over a substrate. A second semiconductor nanostructure is formed over the first semiconductor nanostructure. A first source/drain region is formed interfacing with the first semiconductor nanostructure. A dielectric layer is formed over the first source/drain region. A self-assembled monolayer (SAM) film is formed over the dielectric layer. A second source/drain region is formed over the SAM film.

### BACKGROUND

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other. While existing CFET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2-6 are perspective views of a CFET device at various stages of manufacturing, in accordance with some embodiments of the present disclosure.

FIGS. 7A, 8, 9, 10A, 11, 12, 13A, 14A and 15A illustrate cross-sectional views along a similar cross-section as reference cross-section A-A′ in FIG. 1.

FIGS. 7B, 10B, 13B, 14B and 15B illustrate cross-sectional views along a similar cross-section as reference cross-section B-B′ in FIG. 1.

FIGS. 7C, 10C, 13C, 14C and 15C illustrate cross-sectional views along a similar cross-section as reference cross-section C-C′ in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may mean within 20 percent, or within 10 percent, or within 5 percent of a given value or range. Numerical quantities given herein are approximate, meaning that the term “around,” “about,” “approximately,” or “substantially” can be inferred if not expressly stated.

A Complementary Field-Effect Transistor (CFET) structure and the method of forming the same are provided. Throughout the description, the terms “FET” and “transistor” are used interchangeably. In accordance with some embodiments, A CFET structure includes an n-type FET (NFET) and a p-type FET (PFET), which share a common metal gate (with a common work function material). When the common metal gate has a p-type work function layer, an n-type dipole dopant is doped into the high-k dielectric layer of the NFET. When the common metal gate has an n-type work function layer, a p-type dipole dopant is doped into the high-k dielectric layer of the PFET. While Gate-All-Around (GAA) transistors (such as nanostructure-FETs) are discussed, the concept of the present disclosure can also be applied to the formation of other types of transistors such as planar transistors, Fin Field-Effect Transistors (FinFETs), or the like. Furthermore, in the illustrated examples, the upper FETs are PFETs, and lower FETs are NFETs, while in other embodiments, upper FETs may also be NFETs, and the lower FETs may be PFETs. The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Epitaxial growth of upper epitaxial source/drain regions for the upper FETs may utilize horizontal growth from sidewalls of nanostructures rather than growth from the underlying dielectric layer, such as silicon oxide, which may result in unintended voids between the dielectric layer and the upper epitaxial source/drain regions. As a result, electrical properties and critical dimension (CD) uniformity of the upper source/drain regions may be compromised, leading to decreased device performance.

To address these issues, the present disclosure provides, in various embodiments, the use of self-assembled monolayer (SAM) materials with specific head groups, such as acrylate, which facilitate the immobilization of the SAM on the dielectric surface through hydrophilic interactions. Initially, the SAM forms a highly organized monolayer on the dielectric surface via spin-coating. Subsequently, the acrylate groups can be polymerized using either thermal or photoinitiation, thereby stabilizing the SAM configuration. The silane head groups within the SAM serve as nucleation sites for the vertical growth of the upper epitaxial layer, effectively preventing the formation of voids beneath the upper epitaxial source/drain regions.

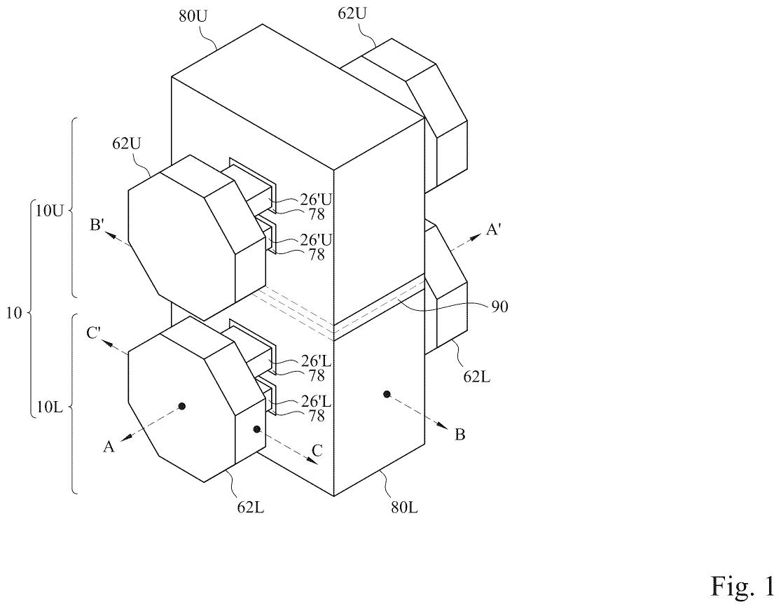

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Cross-section C-C′ is a vertical cross-section that is parallel to cross-section B-B′ and extends through the source/drain regions 62 of the CFETs. Subsequent figures may refer to these reference cross-sections for clarity.

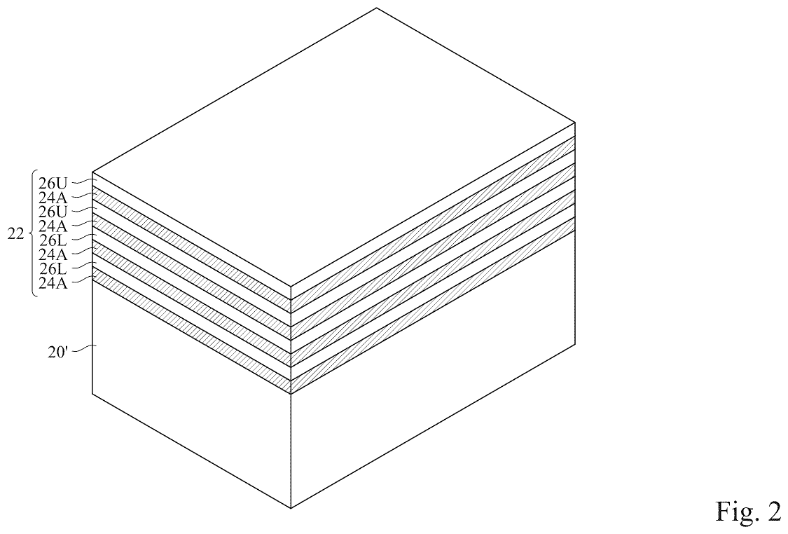

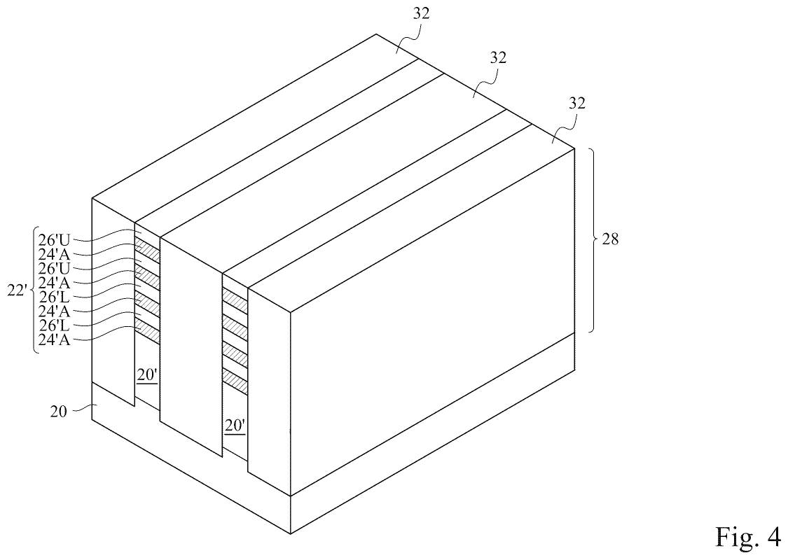

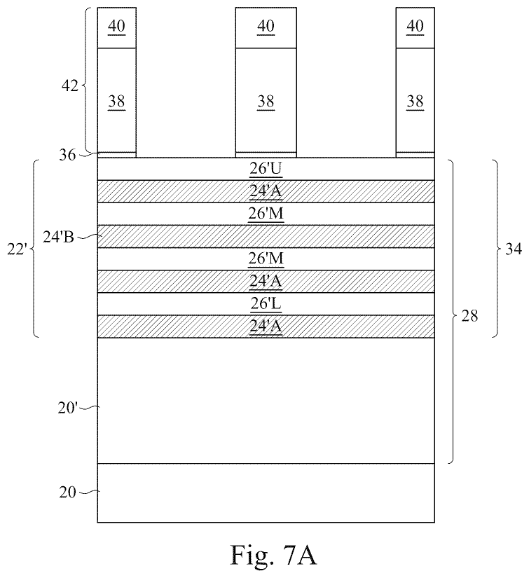

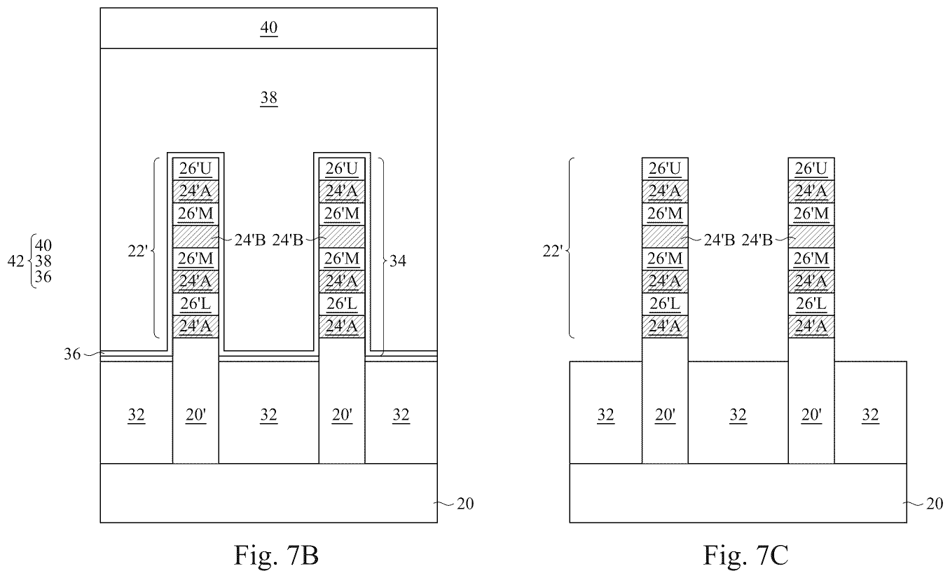

FIGS. 2 through 6 illustrate perspective views of intermediate stages in the formation of CFETs (as schematically represented in FIG. 1) in accordance with some embodiments. FIGS. 7A-15C illustrate cross-sectional views of intermediate stages in the formation of CFETs (as schematically represented in FIG. 1) in accordance with some embodiments. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1. The figures having digits followed by letter “C” illustrate the vertical cross-sectional views along a similar cross-section as the vertical reference cross-section C-C′ in FIG. 1.

In FIG. 2, a wafer 2, which includes a substrate 20, is provided. The substrate 20 may be a semiconductor substrate, such as a a bulk semiconductor, semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

A multi-layer stack 22 is formed over the substrate 20. The multi-layer stack 22 includes alternating dummy semiconductor layers 24 (including dummy semiconductor layers 24A and a dummy semiconductor layer 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, the lower semiconductor layers 26L and the upper semiconductor layers 26U may be in-situ doped (when epitaxially grown) and/or implanted to desirable conductivity types.

In the illustrated example, the multi-layer stack 22 includes three of the dummy semiconductor layers 24 and four of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, the dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in dummy semiconductor layers 24A.

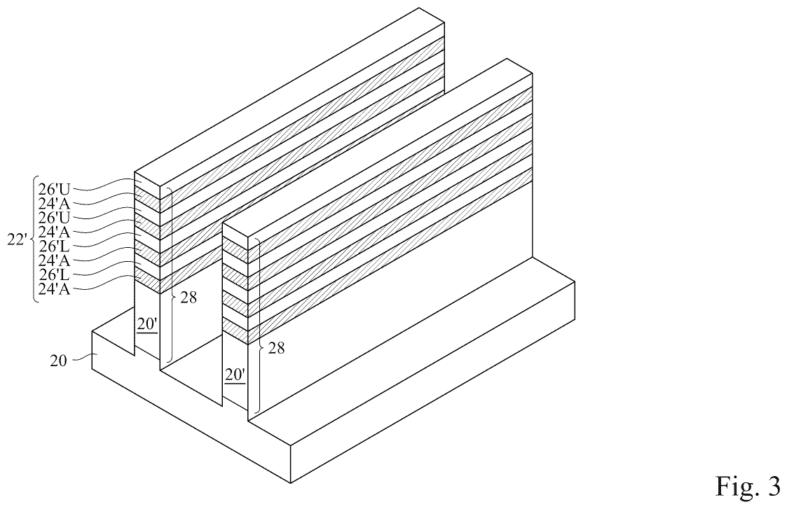

In FIG. 3, the multi-layer stack 22 and the substrate 20 are patterned to form semiconductor strips 28. Each of semiconductor strips 28 includes semiconductor strip 20′ (the portions of the original substrate 20) and multi-layer stack 22′, which is the remaining portion of multi-layer stack 22. The remaining portions 22′ of multi-layers stack 22 are referred to as nanostructures hereinafter, which are referred to using the corresponding reference number followed by a “′” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions or channel layers for lower nanostructure-FETs of the CFETs. The upper semiconductor nanostructures 26′U will act as channel regions or channel layers for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process.

Isolation regions 32 are formed over the substrate 20 and between adjacent semiconductor strips 28. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of isolation regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the isolation regions 32 include silicon oxide formed by an FCVD process, followed by an anneal process.

In FIG. 5, isolation regions 32 are then recessed. Some upper portions of semiconductor strips 28 (including multi-layer stacks 22′) protrude higher than the remaining isolation regions 32 to form protruding fins 34.

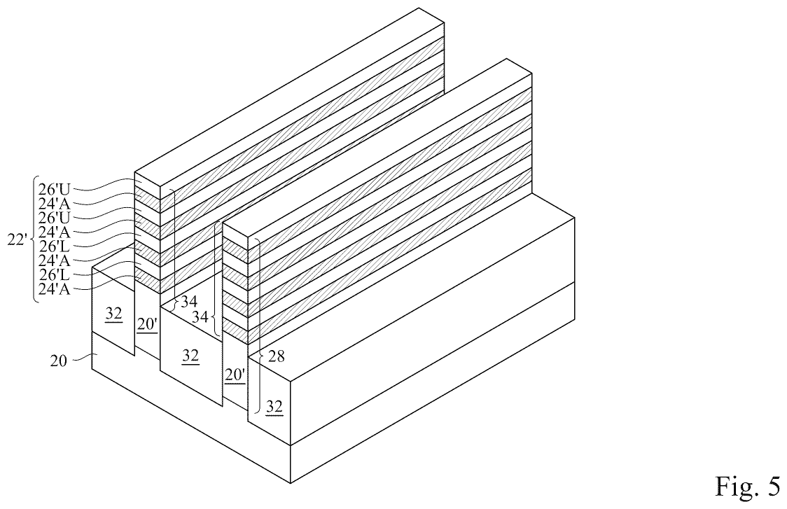

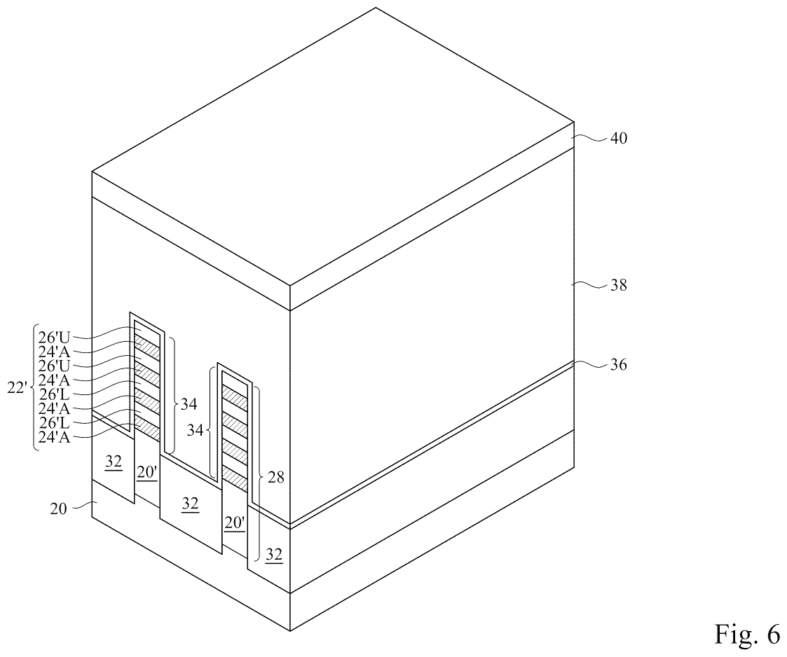

In FIG. 6, a dummy dielectric layer 36 is formed on the protruding fins 34. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

Reference is made to FIGS. 7A-7C. The mask layer 40 may be patterned through photolithography and etching processes to form a mask, which is then used to etch and pattern the dummy gate layer 38, and possibly dummy dielectric layer 36. A resulting structure is shown in FIG. 7A, which illustrates a cross-section along the lengthwise direction of semiconductor strip 28. The remaining portions of mask layer 40, dummy gate layer 38, and dummy dielectric layer 36 form dummy gate stacks 42.

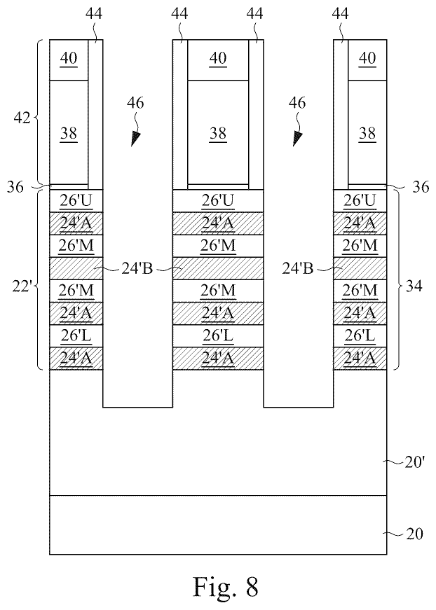

In FIG. 8, gate spacers 44 are formed over the multi-layer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Source/drain recesses 46 are formed in semiconductor strips 28. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

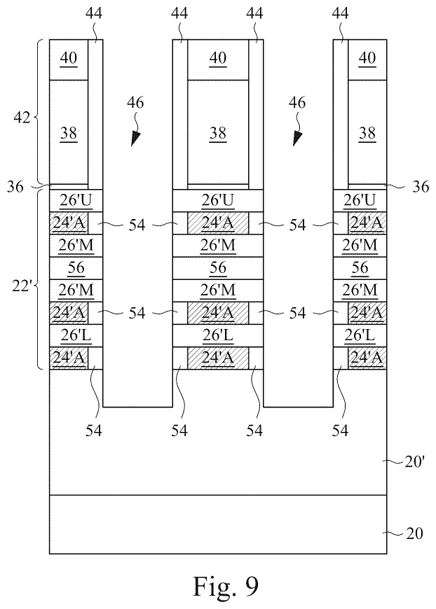

In FIG. 9, inner spacers 54 and dielectric isolation layers 56 are formed. The formation of inner spacers 54 and dielectric isolation layers 56 may include an etching process that laterally etches the dummy nanostructures 24′A (FIG. 8) and removes the dummy nanostructure 24′B.

The etching process may be isotropic and may be selective to the material of the dummy nanostructures 24′A, so that the dummy nanostructures 24′A are etched at a faster rate than the upper and lower semiconductor nanostructures 26′U and 26′L. The etching process may also be selective to the material of the dummy nanostructures 24′B, so that the dummy nanostructures 24′B are etched at a faster rate than the dummy nanostructures 24′A. In this manner, the dummy nanostructures 24′B may be completely removed from between the lower semiconductor nanostructures 26′L (collectively) and the upper semiconductor nanostructures 26′U (collectively) without completely removing the dummy nanostructures 24′A.

In some embodiments where the dummy nanostructures 24′B are formed of germanium or silicon germanium with a high germanium atomic percentage, the dummy nanostructures 24′A are formed of silicon germanium with a low germanium atomic percentage, and the semiconductor nanostructures 26′ (including 26′M, 26′U and 26′L) are formed of silicon free from germanium, the etch process may comprise a dry etch process using chlorine gas, with or without a plasma. Because the dummy gate stacks 42 warp around sidewalls of the semiconductor nanostructures 26′ (see FIG. 6), the dummy gate stacks 42 may support the upper semiconductor nanostructures 26′U so that the upper semiconductor nanostructures 26′U do not collapse upon removal of the dummy nanostructures 24′B. Further, although sidewalls of the dummy nanostructures 24′A are illustrated as being straight after the etching, the sidewalls may be concave or convex.

Inner spacers 54 are formed on sidewalls of the recessed dummy nanostructures 24′A, and dielectric isolation layers 56 are formed between the upper semiconductor nanostructures 26′U (collectively) and the lower semiconductor nanostructures 26′L (collectively). In the subsequent formation of source/drain regions, the inner spacers 54 may act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26′U (collectively) from the lower semiconductor nanostructures 26′L (collectively). Furthermore, middle semiconductor nanostructures 26′M and dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, and between the upper and lower semiconductor nanostructures 26′U and 26′L, and then etching the insulating material. The insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 24′A (thus forming the inner spacers 54) and has portions remaining in between the upper and lower semiconductor nanostructures 26′U and 26′L (thus forming the dielectric isolation layers 56).

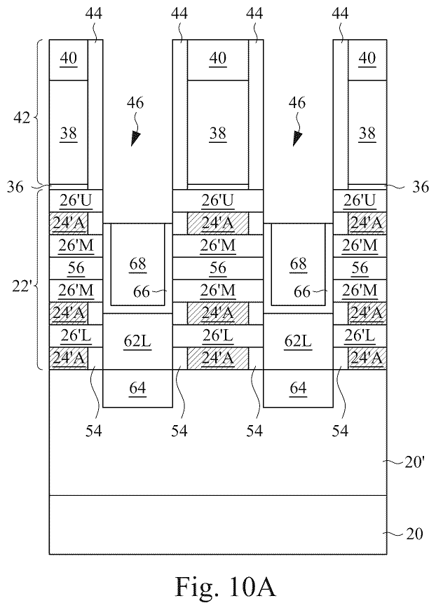

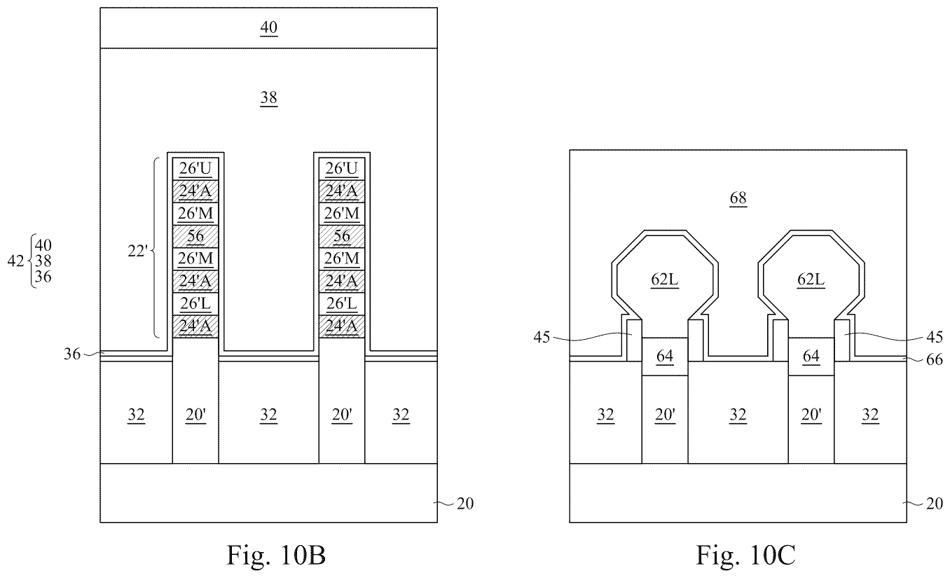

As also illustrated by FIGS. 10A-10C, a dielectric material 64 is formed in the source/drain recesses 46 and on the semiconductor strips 20′. The dielectric material 64 may be formed by forming a dielectric material in the source/drain recesses 46 and subsequently recessing the dielectric material. Acceptable dielectric materials may include silicon nitride, silicon oxide, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to recess the dielectric material. The etching may be isotropic, such as an etch-back process that removes a desired amount of the dielectric material from the source/drain recesses 46.

Next, lower epitaxial source/drain regions 62L and upper epitaxial source/drain regions 62U are formed on the dielectric material 64 in the source/drain recesses 46. The lower epitaxial source/drain regions 62L are formed in the lower portions of the source/drain recesses 46. The lower epitaxial source/drain regions 62L are in contact with the lower semiconductor nanostructures 26′L and are not in contact with the upper semiconductor nanostructures 26′U. The lower epitaxial source/drain regions 62L can be on opposite sides of the lower semiconductor nanostructures 26′L. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like.

The lower epitaxial source/drain regions 62L may be in-situ doped, and may be, or may not be, implanted with the corresponding p-type or n-type dopants. During the epitaxy of the lower epitaxial source/drain regions 62L, the upper semiconductor nanostructures 26′U may be masked to prevent undesired epitaxial growth on the upper semiconductor nanostructures 26′U. After the lower epitaxial source/drain regions 62L are grown, the masks on the upper semiconductor nanostructures 26′U may then be removed.

A first Contact Etch Stop Layer (CESL) 66 and a first Inter-Layer Dielectric (ILD) 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include SiO₂, phospho-silicate glass (PSG), boro-silicate glass (BSG), boron-doped phospho-silicate glass (BPSG), undoped silicate glass (USG), or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

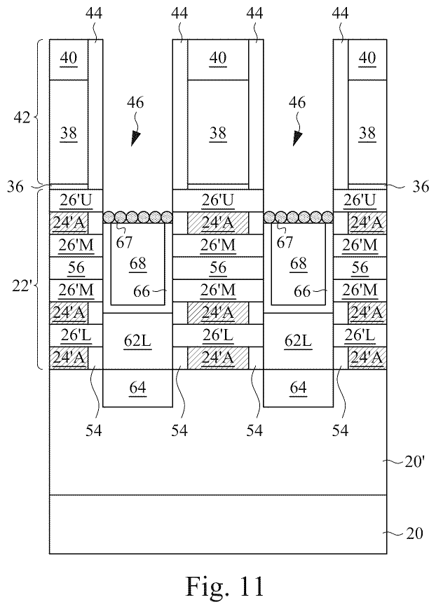

Reference is made to FIG. 11. In some embodiments, a self-assembled monolayer (SAM) film 67 is formed over the first ILD 68 and the first CESL 66 before forming the upper epitaxial source/drain regions 62U over the first ILD 68 and the first CESL 66. The SAM film 67 is configured to provide a crystalline or highly ordered monolayer on the first ILD 68 and the first CESL 66, thereby serving as nucleation sites for the vertical epitaxial growth of a subsequently formed upper epitaxial source/drain regions from the SAM film 67, thereby preventing the formation of voids beneath the upper epitaxial source/drain regions. For example, the SAM film 67 can be highly ordered through hydrophilic interactions with the first ILD 68. Therefore, unintended voids between the first ILD 68 and the upper epitaxial source/drain regions 62U can be prevented. The SAM film 67 can be an organized layer of molecules that can be tailored such that one end of the molecule, a “head group,” shows an affinity for dielectric surfaces and an aversion for metal surfaces. The head group is connected to an alkyl chain in which a tail or “terminal end” can be functionalized, for example, to vary wetting and interfacial properties. The head group is connected to a “terminal end” (a functional group) through a chain. In some embodiments, affinity and aversion characteristics can be achieved for a wide range of surfaces by choosing different compound types of head groups. In some embodiments, the SAM film 67 includes a head group such as acrylate, which enables immobilization of the SAM on a dielectric surface with a certain degree of mobility through hydrophilic interaction. In some embodiments, the SAM film 67 can have a formula (a) or a formula (b):

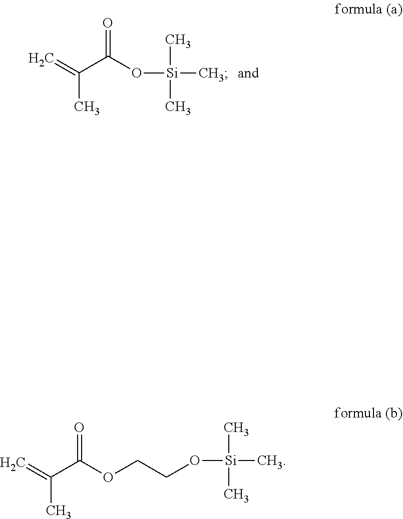

In some embodiments, the SAM film 67 can include a head group such as silane which can serve as seeds for the epitaxial growth of the upper epitaxial source/drain regions 62U. In some embodiments, since the SAM film 67 may be organic and is more instability during a thermal treatment, the epitaxial growth of upper epitaxial source/drain regions 62U can be implemented at a low temperature which can be lower than about 400° C. For example, if the epitaxial growth of the upper epitaxial source/drain regions 62U is implemented at a temperature greater than about 400° C., the SAM film 67 may be unstable.

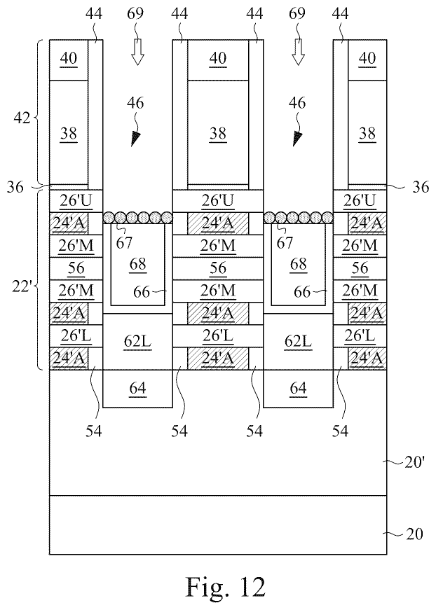

In some embodiments, the SAM film 67 can form a highly organized monolayer on the first CESL 68 via a suitable deposition process, such as spin on process. Reference is made to FIG. 12. In certain embodiments, the SAM film 67 may be treated with or added with a thermal initiator 69 or a photo initiator 69, which triggers the polymerization of its acrylate groups. This chemical reaction results in a more robust and stable film structure, ensuring that the SAM film 67 retains its intended configuration over time. The polymerization involves the formation of a polymer network through the linkage of acrylate monomers. During this process, the carbon-carbon double bonds in the acrylate monomers (see formula (a) and formula (b)) are broken, facilitating the formation of a robust polymer network that reinforces the film's structure and maintains its configuration.

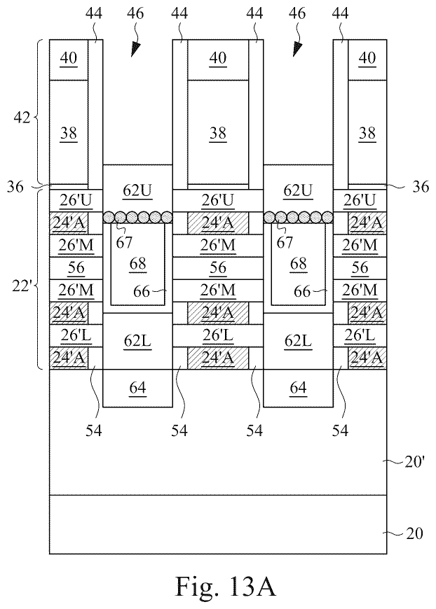

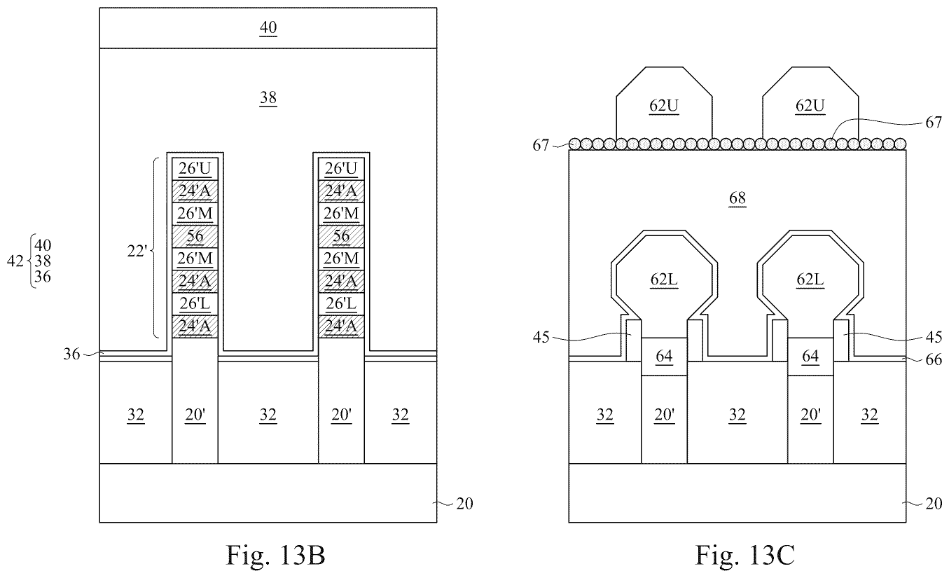

In FIGS. 13A-13C, upper epitaxial source/drain regions 62U are then formed in the upper portions of the source/drain recesses 46 and over the SAM film 67. The upper epitaxial source/drain regions 62U can be formed through a combination of lateral and vertical epitaxial growth processes. Specifically, the end surfaces of the upper semiconductor nanostructures 26′U act as nucleation sites for the lateral growth of the upper epitaxial source/drain regions 62U, while the top surfaces of the SAM films 67 serve as nucleation sites for the vertical growth of the upper epitaxial source/drain regions 62U. This dual growth approach facilitates that the upper epitaxial source/drain regions 62U are formed without voids beneath them. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. For example, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant. Adjacent upper source/drain regions 62U may remain separated after the epitaxy process or may be merged.

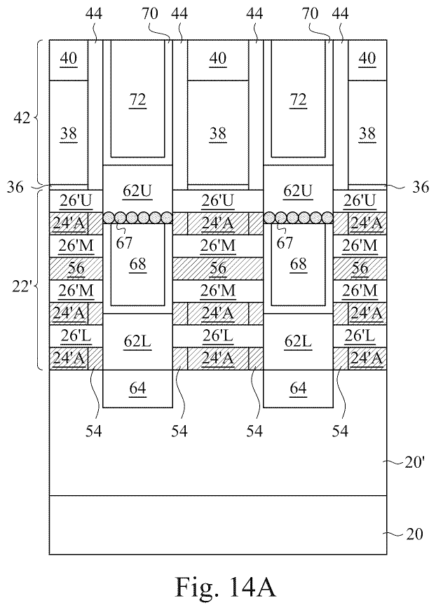

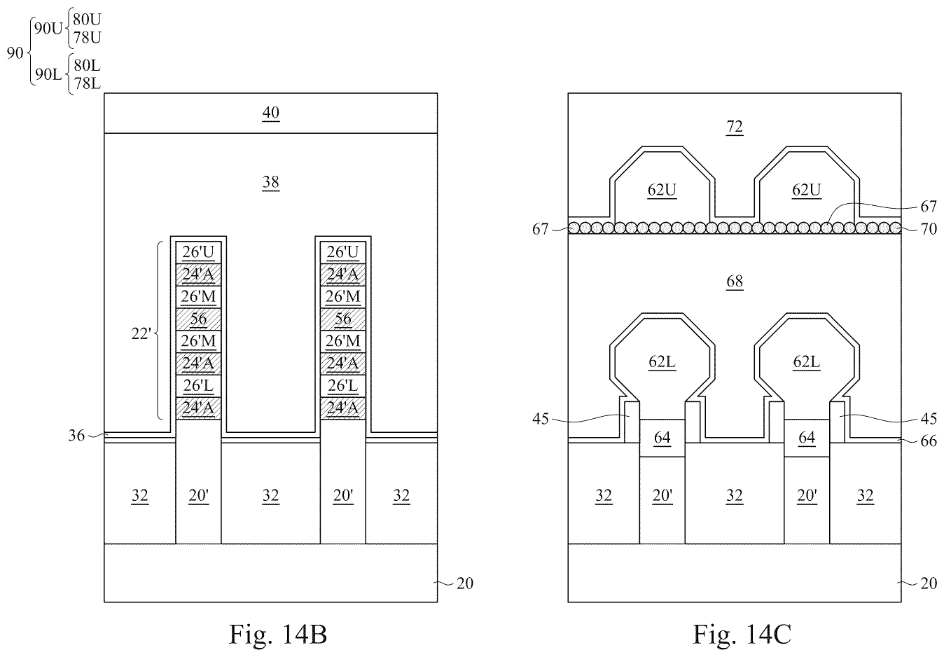

In FIGS. 14A-14C, after the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for the second CESL 70 and the second ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove mask layers 40, or leave mask layers 40 unremoved.

Replacement gate stacks are then formed to replace the dummy gate stacks 42. The dummy gate stacks 42 are first removed in one or more etching processes to exposes the multi-layer stacks 22′.

The remaining portions of the dummy nanostructures 24′A are then removed through etching. In the etching process, the dummy nanostructures 24′A are etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

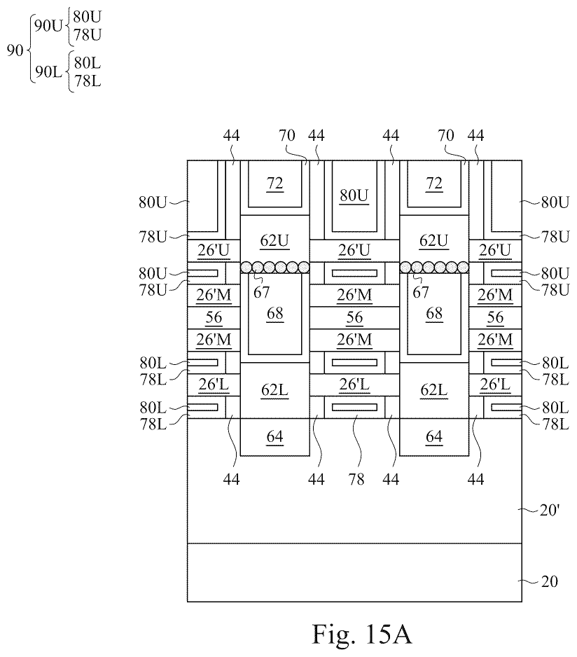

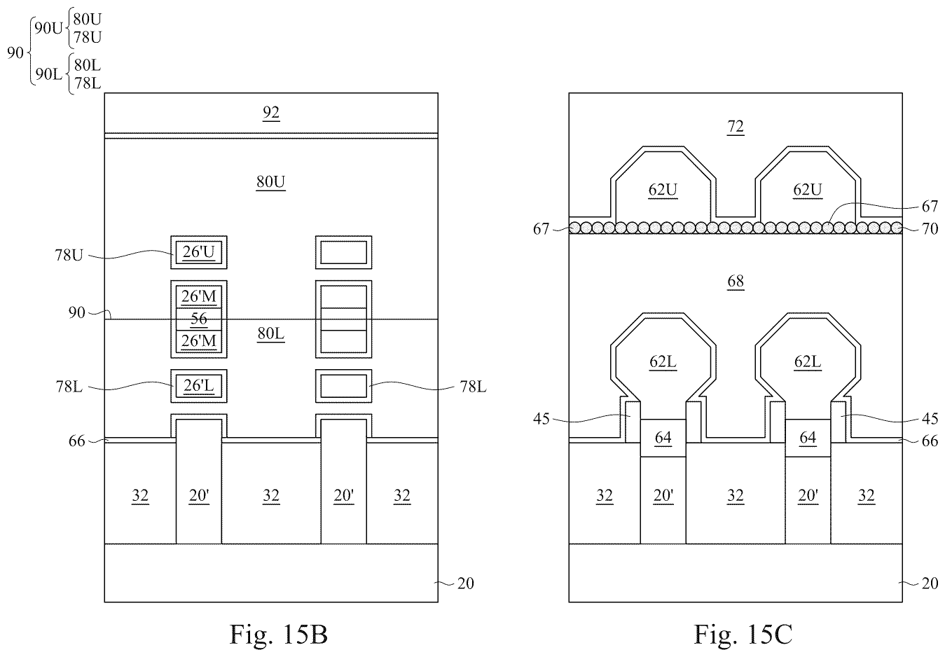

In FIGS. 15A-15C, gate dielectrics 78U and 78L are formed as parts of a conformal liner on the exposed semiconductor nanostructures 26′. The gate dielectrics 78U and 78L are formed on the exposed surfaces of the exposed features including the semiconductor nanostructures 26′ and the gate spacers 44. The gate dielectrics 78U and 78L wrap around all (e.g., four) sides of the semiconductor nanostructures 26′.

Gate dielectrics 78U and 78L are formed to encircle upper semiconductor nanostructures 26′U, middle semiconductor nanostructures 26′M, and lower semiconductor nanostructures 26′L. Each of the gate dielectrics 78U and 78L may include an interfacial layer which may be formed of or comprise a group IV element, a group III element, and/or a group V element. Interfacial layer may include an oxide such as silicon oxide or a metal oxide, a silicate such as a metal silicate, combinations thereof, multi-layers thereof, or the like. The interfacial layer may be formed of a thermal oxidation process and/or a deposition process.

The gate dielectrics 78U and 78L may also include high-k dielectric layers which have a high dielectric constant (high-k) value greater than, for example, about 7.0, about 21, or higher. High-k dielectric layers may be formed of or comprise a metal oxide or a silicate of a metal selected from hafnium, zirconium, barium, titanium, lead, and combinations thereof. The formation methods of high-k dielectric layers may be selected from Molecular-Beam Deposition (MBD), ALD, PECVD, and the like. The gate dielectrics 78U and 78L in the upper FET region and the lower FET region are formed in common processes.

Upper and lower gate electrodes 80U and 80L can then be formed over the gate dielectrics 78U and 78L, respectively. Gate dielectrics 78U and 78L and the respective gate electrodes 80U and 80L are collectively referred to as gate stacks 90, which include upper gate stack 90U and lower gate stack 90L. The resulting upper FET 10U and lower FET 10L share a common gate electrode 80. The upper portion of the gate electrode 80 that is higher than dielectric isolation layer 56 is referred to as upper gate electrode 80U. The lower portion of the gate electrode that is lower than dielectric isolation layer 56 is referred to as lower gate electrode 80L.

Gate electrodes 80 may include a plurality of layers include TIN, TaN, or the like, and may include one or more work function layers and filling metal regions. Filling metal regions may comprise tungsten, ruthenium, cobalt, combinations thereof, multi-layers thereof, or the like.

In accordance with some embodiments, the work function layers have a p-type work function, which is higher than about 4.6 eV, and may be in the range between about 4.6 eV and about 5.2 eV. The n-type FETs, however, prefer n-type work functions, which have low work function values, for example, smaller than about 4.5 eV, or between about 4.0 eV and about 4.5 eV.

The embodiments of the present disclosure have some advantageous features. An SAM can be formed over the first ILD prior to forming the upper epitaxial source/drain regions. The SAM is configured to provide a crystalline or highly ordered monolayer on the first ILD as a template for the epitaxial growth of the upper epitaxial source/drain regions from the bottom. Therefore, unintended voids between the first ILD and the upper epitaxial source/drain regions can be prevented.

In some embodiments, a method comprises the following steps. A first semiconductor nanostructure is formed over a substrate. A second semiconductor nanostructure is formed over the first semiconductor nanostructure. A first source/drain region is formed interfacing with the first semiconductor nanostructure. A dielectric layer is formed over the first source/drain region. A self-assembled monolayer (SAM) film is formed over the dielectric layer. A second source/drain region is formed over the SAM film. In some embodiments, the SAM film comprises a formula (a):

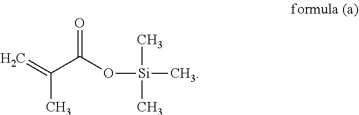

In some embodiments, the SAM film comprises a formula (b):

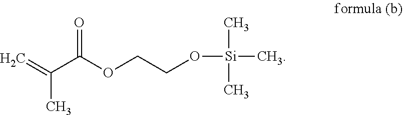

In some embodiments, the method further comprises after forming the SAM film over the dielectric layer, adding a photo initiator to the SAM film. In some embodiments, the method further comprises after forming the SAM film over the dielectric layer, adding a thermal initiator to the SAM film. In some embodiments, the SAM film comprises silane. In some embodiments, the dielectric layer is silicon oxide. In some embodiments, the SAM film and the dielectric layer have a hydrophilic interaction.

In some embodiments, a method comprises the following steps. A first channel region is formed over a substrate. A second channel region is formed over the first channel region. A first doped epitaxial region is formed in contact with the first channel region. A dielectric region is formed over the first doped epitaxial region. A silane-containing film is formed over the dielectric region. Second doped epitaxial region is formed in contact with the second channel region and the silane-containing film. A gate structure is formed surrounding the first channel region and the second channel region. In some embodiments, forming the silane-containing film comprises forming the silane-containing film using spin on process. In some embodiments, the method further comprises prior to forming the second doped epitaxial source/drain regions over the silane-containing film, adding a photo initiator to the silane-containing film. In some embodiments, the method further comprises prior to forming the second doped epitaxial source/drain regions over the silane-containing film, adding a thermal initiator to the silane-containing film. In some embodiments, the silane-containing film and the dielectric region have a hydrophilic interaction. In some embodiments, the silane-containing film comprises an acrylate. In some embodiments, the method further comprises after forming the silane-containing film over the dielectric region, polymerizing the silane-containing film. In some embodiments, forming the silane-containing film over the dielectric region comprises forming the silane-containing film at a temperature lower than about 400° C.

In some embodiments, a semiconductor device comprises a substrate, a first channel layer over the substrate, first epitaxial source/drain regions adjoining opposite ends of the first channel layer, a second channel layer over the first channel layer, dielectric layers over the first epitaxial source/drain regions, respectively, second epitaxial source/drain regions over the dielectric layers, the second epitaxial source/drain regions adjoining opposite ends of the second channel layer, and a first silane-containing film vertically between a first one of the dielectric layers and a first one of the second epitaxial source/drain regions. In some embodiments, the semiconductor device further comprises a second silane-containing film vertically between a second one of the dielectric layers and a second one of the second epitaxial source/drain regions. In some embodiments, the first silane-containing film comprises a formula (a):

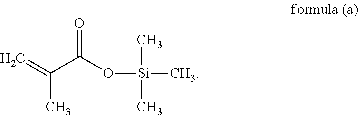

In some embodiments, the first silane-containing film comprises a formula (b):

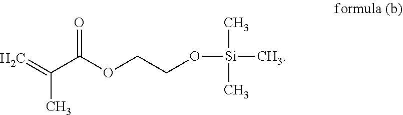

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor nanostructure over a substrate;
forming a second semiconductor nanostructure over the first semiconductor nanostructure;
forming a first source/drain region interfacing with the first semiconductor nanostructure;
forming a dielectric layer over the first source/drain region;
forming a self-assembled monolayer (SAM) film over the dielectric layer; and
forming a second source/drain region over the SAM film.

2. The method of claim 1, wherein the SAM film comprises a formula (a):

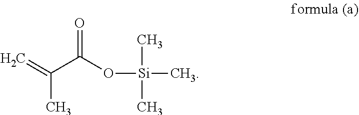

3. The method of claim 1, wherein the SAM film comprises a formula (b):

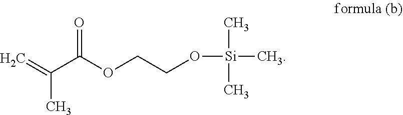

4. The method of claim 1, further comprising:
after forming the SAM film over the dielectric layer, adding a photo initiator to the SAM film.

5. The method of claim 1, further comprising:
after forming the SAM film over the dielectric layer, adding a thermal initiator to the SAM film.

6. The method of claim 1, wherein the SAM film comprises silane.

7. The method of claim 6, wherein the dielectric layer is silicon oxide.

8. The method of claim 7, wherein the SAM film and the dielectric layer have a hydrophilic interaction.

9. A method, comprising:
forming a first channel region over a substrate;
forming a second channel region over the first channel region;
forming a first doped epitaxial region in contact with the first channel region;
forming a dielectric region over the first doped epitaxial region;
forming a silane-containing film over the dielectric region;
forming a second doped epitaxial region in contact with the second channel region and the silane-containing film; and
forming a gate structure surrounding the first channel region and the second channel region.

10. The method of claim 9, wherein forming the silane-containing film comprises forming the silane-containing film using spin on process.

11. The method of claim 9, further comprising:
prior to forming the second doped epitaxial source/drain regions over the silane-containing film, adding a photo initiator to the silane-containing film.

12. The method of claim 9, further comprising:
prior to forming the second doped epitaxial source/drain regions over the silane-containing film, adding a thermal initiator to the silane-containing film.

13. The method of claim 9, wherein the silane-containing film and the dielectric region have a hydrophilic interaction.

14. The method of claim 9, wherein the silane-containing film comprises an acrylate.

15. The method of claim 9, further comprising:
after forming the silane-containing film over the dielectric region, polymerizing the silane-containing film.

16. The method of claim 9, wherein forming the silane-containing film over the dielectric region comprises forming the silane-containing film at a temperature lower than about 400° C.

17. A semiconductor device, comprising:
a substrate;
a first channel layer over the substrate;
first epitaxial source/drain regions adjoining opposite ends of the first channel layer;
a second channel layer over the first channel layer;
dielectric layers over the first epitaxial source/drain regions, respectively;
second epitaxial source/drain regions over the dielectric layers, the second epitaxial source/drain regions adjoining opposite ends of the second channel layer; and
a first silane-containing film vertically between a first one of the dielectric layers and a first one of the second epitaxial source/drain regions.

18. The semiconductor device of claim 17, further comprising:
a second silane-containing film vertically between a second one of the dielectric layers and a second one of the second epitaxial source/drain regions.

19. The semiconductor device of claim 17, wherein the first silane-containing film comprises a formula (a):

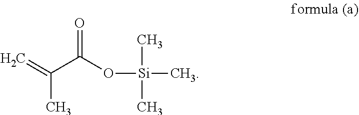

20. The semiconductor device of claim 17, wherein the first silane-containing film comprises a formula (b): [chemical structure]
